(19) United States
(12) Patent Application Publication
(10) Pub. No.: US 2025/0374438 A1
(43) Pub. Date: Dec. 4, 2025

(54) METHOD FOR PREPARING MICRO-NANO FLEXIBLE CONDUCTIVE CIRCUIT BASED ON ULTRASONIC DRIVING OF LIQUID METAL

(71) Applicant: HARBIN INST. OF TECH (SHENZHEN) (INST. OF SCIENCE AND TECH INNOVATION, HARBIN INST. OF TECH), Guangdong (CN)

(72) Inventors: Xing MA, Guangdong (CN); Zirong XU, Guangdong (CN); Dongdong JIN, Guangdong (CN); Sanhu LIU, Guangdong (CN); Zhiwu XU, Guangdong (CN)

(73) Assignee: HARBIN INST. OF TECH (SHENZHEN) (INST. OF SCIENCE AND TECH INNOVATION, HARBIN INST. OF TECH), Guangdong (CN)

(21) Appl. No.: 18/888,127

(22) Filed: Sep. 17, 2024

(30) Foreign Application Priority Data
May 29, 2024 (CN) 202410676185.1

(51) Int. Cl. H05K 3/10; B22D 19/00; B22D 27/08; B29C 39/02; B29C 39/42; B29K 83/00; B29L 31/34; H05K 3/00

(52) U.S. Cl. CPC H05K 3/101; B22D 19/009; B22D 27/08; B29C 39/026; B29C 39/42; H05K 3/0014; B29K 2083/00; B29L 2031/3493; H05K 2203/1305

(57) ABSTRACT

A method for preparing a micro-nano flexible conductive circuit based on ultrasonic driving of liquid metal comprises the following steps: preparing a mold with a channel pattern and a liquid metal chamber by 3D printing, and adding a well-mixed flexible substrate resin mixture into the mold; then, eliminating bubbles, curing, and stripping from the mold to obtain a bottom-uncovered flexible substrate; covering the bottom of the bottom-uncovered flexible substrate with a base plate to obtain a bottom-covered flexible substrate mold; fixing the bottom-covered flexible substrate mold on a metal fixture table, injecting liquid metal into the liquid metal chamber, allowing an ultrasonic welding machine to come in contact with the fixture table on one side, and applying ultrasound to fill the liquid metal in a channel; and removing the base plate to obtain a liquid metal flexible conductive circuit.

### CROSS-REFERENCE TO RELATED APPLICATION

This application claims the priority benefit of China application serial no. 202410676185.1, filed on May 29, 2024. The entirety of the above-mentioned patent application is hereby incorporated by reference herein and made a part of this specification.

### BACKGROUND OF THE INVENTION

### 1. Technical Field

The invention relates to the technical field of preparation of electronic components, and particularly relates to a method for preparing a micro-nano flexible conductive circuit based on ultrasonic driving of liquid metal.

### 2. Description of Related Art

At present, there are mainly two types of liquid metal patterning methods for preparing flexible electronic conductive circuits, which are respectively direct patterning methods that directly deposit liquid metal to a specified region, and indirect patterning methods that prepare a flexible channel and then fill the flexible channel with liquid metal. Wherein, the indirect liquid metal patterning methods mainly includes: an injection method and a vacuum method. According to the injection method, liquid metal is pressed into a flexible channel by means of an injector under the action of an external pressure. According to the vacuum method, liquid metal is placed at inlet of a channel, and a flexible device is placed in a vacuum environment; and when the flexible device is transferred from the vacuum environment back to the atmospheric environment, the liquid metal will be pressed into the channel because the air pressure in the channel is lower than the air pressure in the outside, such that the channel is filled with the liquid metal. The indirect patterning methods mainly have the following two features: 1, a flexible substrate is prepared from PDMS, Ecoflex and other materials, and a channel required for a liquid metal circuit has been machined in the flexible substrate; 2, the channel is completely filled with liquid metal under the action of an external pressure (the injector and the atmospheric pressure). Hence, after the channel is fully filled with liquid metal, the dimension of the channel is equivalent to the accuracy of the flexible liquid metal circuit prepared by the indirect patterning methods.

The injection method, as one of the indirect patterning methods, injects liquid metal into a channel by means of a pressure. The dimension of the channel is in reverse proportion to the pressure required for filling, that is, the finer the channel to be filled, the higher the pressure intensity required, and an excessively high pressure will destroy the package of the flexible substrate and lead to a leakage of liquid metal, thus damaging the flexible device. As a result, the injection method has the following limitations: (1) the injection method cannot be used for processing high-accuracy liquid metal circuits because of its low dimension accuracy, and the minimum dimension of liquid metal circuits prepared by the injection method is 50 μm as reported in existing literature; (2) the injection method cannot realize filling of complex channel structures such as multi-channel structures, blind-hole structures and interconnected-channel structures. Limited by the nature of the injection method, a channel should have an inlet and an outlet, so blind-hole structures cannot be filled by means of the injection method; and in the presence of multiple channels or interconnected channels, liquid tends to flow to the outlet of the channel with a small resistance, making it impossible to completely fill in all the channels, as shown in FIG. 1.

To protect the flexible substrate, researchers develop the vacuum method based on the injection method. The vacuum method fills a channel with liquid metal by means of the atmospheric pressure, such that the flexible substrate can be well protected, and the plane accuracy can reach 10 μm. However, the vacuum preparation time (the time for vacuumizing the channel in the flexible substrate) is at least 30 min or longer, leading to low production efficiency; in the presence of complex patterns and a great many corners, insufficient filling may occur. As a result, the vacuum method has the following limitations: (1) the accuracy is limited due to the limitation of atmospheric pressure, and the limit of liquid metal patterning accuracy of the vacuum method is 10 μm as reported in existing literature; (2) the preparation time is long (the processing time is long and the efficiency is low), it takes at least 30 min to realize a vacuum environment in the channel to generate a pressure difference; (3) insufficient filling may occur, and in the presence of a great many corners, the injection method may have the problem of insufficient filling.

### BRIEF SUMMARY OF THE INVENTION

In view of the above technical problems, the invention discloses a method for preparing a micro-nano flexible conductive circuit based on ultrasonic driving of liquid metal to solve the problems of low accuracy, long preparation time and failure to fill in complex channels of traditional indirect patterning methods.

To fulfill the above purpose, the invention adopts the following technical solution:

A method for preparing a micro-nano flexible conductive circuit based on ultrasonic driving of liquid metal comprises the following steps:
S1, preparing a mold with a channel pattern and a liquid metal chamber, and adding a well-mixed flexible substrate resin mixture into the mold;
S2, placing the mold full of the flexible substrate resin mixture in a vacuum environment to eliminate bubbles, curing, and stripping a cured flexible substrate from the mold to obtain a bottom-uncovered flexible substrate;
S3, covering a bottom of the bottom-uncovered flexible substrate with a base plate to obtain a bottom-covered flexible substrate mold;
S4, fixing the bottom-covered flexible substrate mold on a titanium alloy fixture table, injecting liquid metal into the liquid metal chamber of the bottom-covered flexible substrate mold, positioning an ultrasonic welding machine on a side of the fixture table and the bottom-covered flexible substrate mold on an opposite side, and then applying ultrasound to ultrasonically drive the liquid metal in the liquid metal chamber to fill the channel; and
S5, removing the base plate from the bottom-covered flexible substrate mold to obtain a liquid metal flexible conductive circuit.
wherein, the liquid metal is Ga-based liquid metal. By adopting this technical solution, the Ga-based liquid metal is in a liquid state at room temperature and has fluidity, thus being easy to fill; in addition, the Ga-based liquid metal contains Ga that can be oxidized by oxygen to generate an oxide film, and the oxide film can be adhered to must substrates to keep the liquid metal injected into the channel being adhered into the channel, such that the liquid metal will not flow back under the action of its surface tension. In this way, the liquid metal can be ultrasonically driven to fill ultra-fine channels.

According to the technical solution of the invention, an ultrasonic driving method is adopted, ultrasound is introduced as a pressure source to induce a non-uniform acoustic pressure distribution in the liquid metal, and the liquid metal is pressed from a positive-acoustic pressure region (the liquid metal chamber) into a negative-acoustic pressure region (the channel) by means of an acoustic pressure gradient, such that the liquid metal is driven to filled in a micro-nano channel to obtain a flexible electronic conductive circuit.

As a further improvement of the invention, in S4, power of the ultrasound is 400-800 W.

As a further improvement of the invention, in S4, an ultrasonic probe is used to vertically apply ultrasound to the fixture table.

As a further improvement of the invention, in S4, the ultrasonic probe is pressed on the fixture table by means of an air pressure of an air compressor, and a pressure intensity of the air compressor is 0.3-0.5 MPa.

As a further improvement of the invention, a distance between the ultrasonic probe and the bottom-covered flexible substrate mold is not greater than 100 mm. Further, the distance between the ultrasonic probe and the bottom-covered flexible substrate mold is 30-75 mm.

As a further improvement of the invention, in S3, the bottom of the bottom-uncovered flexible substrate is connected to the base plate by means of a PDMS solution and cured to obtain the bottom-covered flexible substrate mold.

As a further improvement of the invention, the base plate is a PMMA board.

As a further improvement of the invention, the flexible substrate resin mixture comprises PDMS and a curing agent. Further, a mass ratio of the PDMS to the curing agent is 10:0.5-2. Further, the mass ratio of the PDMS to the curing agent is 10:1.

As a further improvement of the invention, the metal fixture table is made from titanium alloy or aluminum alloy. Further, the metal fixture table is made from titanium alloy.

The invention discloses a micro conductive circuit, which is prepared by the method for preparing a micro-nano flexible conductive circuit based on ultrasonic driving of liquid metal described above.

The invention discloses a flexible electronic device, comprising the micro conductive circuit.

### BRIEF DESCRIPTION OF THE SEVERAL VIEWS OF THE DRAWINGS

FIG. 1 illustrates results of complex channel structures filled by means of an injection method in the prior art, wherein a) of FIG. 1 illustrates the result of a multi-channel structure, and b) of FIG. 1 illustrates the result of an interconnected-channel structure.

FIG. 2 is a flow diagram of filling in a flexible channel by means of ultrasonic driving of liquid metal according to one embodiment of the invention.

FIG. 3 illustrates velocity statistical results of an ultrasonic driving method according to one embodiment of the invention, wherein a of FIG. 3 illustrates the liquid metal filling velocity of the ultrasonic driving method under different ultrasonic power and channel dimensions, and b of FIG. 3 illustrates the comparison in liquid metal filling velocity of the ultrasonic driving method and the traditional injection method.

FIG. 4 illustrates observation results of channels with different widths/heights prepared by the ultrasonic driving method, obtained by an optical microscope and Micro-CT scanning according to one embodiment of the invention, wherein a of FIG. 4 illustrates the observation results obtained by the optical microscope, and b of FIG. 4 illustrates the observation results obtained by Micro-CT scanning.

FIG. 5 illustrates the comparison of a 750 nm channel before and after liquid metal filling based on ultrasonic driving according to one embodiment of the invention, wherein a of FIG. 5 illustrates the channel before ultrasound application, and b of FIG. 5 illustrates the channel after ultrasound application.

FIG. 6 illustrates simulation results of a channel filled with liquid metal in an ultrasonic driving chamber according to one embodiment of the invention, wherein a of FIG. 6 illustrates acoustic pressure distributions in the chamber and the channel, b of FIG. 6 illustrates a velocity distribution and flow line of liquid metal in the chamber, and c of FIG. 6 illustrates a simulated flow velocity and flow line in the liquid metal filing process.

FIG. 7 illustrates results of complex micro-channel patterns filled with the ultrasonic driving method according to one embodiment of the invention, where a of FIG. 7 illustrates a filling process and result of three channels connected to an LED array, b of FIG. 7 illustrates the filling results of 32 channels connected to a single-chip microcomputer in cases where the ultrasonic driving method and the injection method are used, c of FIG. 7 illustrates the filling results of an interconnected-channel spider-man pattern in cases where the ultrasonic driving method and the injection method are used, and d of FIG. 7 illustrates filling results of a snowflake pattern with a planar structure and blind-hole structures in cases where the ultrasonic driving method and the injection method are used.

FIG. 8 illustrates a result of a comb-like micro-channel pattern filled by the ultrasonic driving method according to one embodiment of the invention.

FIG. 9 illustrates images of a channel obtained by applying ultrasound at different positions and directions according to one embodiment of the invention, wherein in a-d of FIG. 9, the distances between the chambers in different directions and the center of an ultrasonic probe for applying ultrasound are 40 mm, 35 mm, 30 mm and 40 mm respectively.

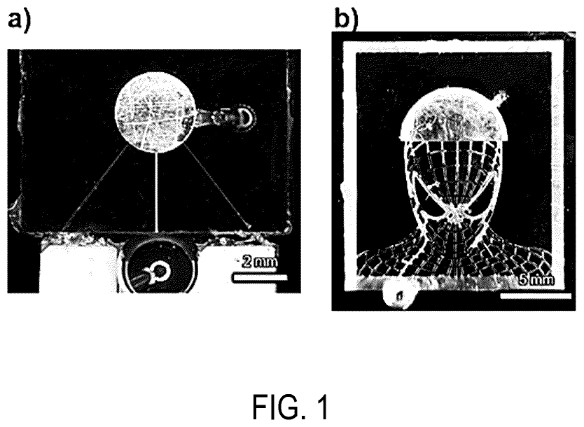

### DETAILED DESCRIPTION OF THE INVENTION

Preferred embodiments of the invention are described in further detail below.

### Embodiment 1

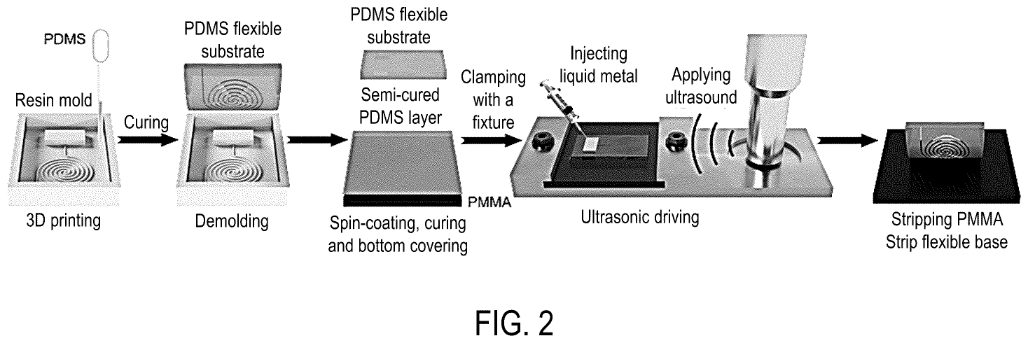

A method for preparing a micro-nano flexible conductive circuit based on ultrasonic driving of liquid metal, with a PDMS flexible substrate as an example (other flexible substrates are also applicable, the PDMS flexible substrate has good light transmission, can facilitate the display of filling results and thus is used as an example), uses an ultrasonic driving method to prepare a flexible liquid metal conductive circuit. As shown in FIG. 2, the method specifically comprises the following steps:

Step 1, mold printing: a resin mold with a channel pattern and a liquid metal chamber was prepared by 3D printing, and a well-mixed PDMS solution (the ratio of PDMS to a curing agent is 10:1) was dropwise added into the mold.

Step 2, demolding: the mold full of the PDMS solution was placed in a vacuum environment for 0.5 h to eliminate bubbles and was heated in an oven at a temperature of 60° C. for 2 hrs to cure PDMS, and then a PDMS flexible substrate was stripped from the resin mold by means of tweezers to obtain a bottom-uncovered PDMS flexible substrate.

Step 3, spin-coating, curing and bottom covering: 0.5 mL of the PDMS solution was dropwise added onto a well-cut PMMA acrylic board (30 mm*30 mm*2 mm) and evenly spread on the PMMA board by spin-coating at a speed of 750 rpm for 1 min; the PMMA board was placed in the oven at the temperature of 60° C. for half an hour to make a PDMS layer in a semi-cured state, the bottom-uncovered PDMS flexible substrate obtained in Step 2 was placed on the semi-cured PDMS layer, and then the bottom-uncovered PDMS flexible substrate and the semi-cured PDMS layer where placed together in the oven at the temperature of 60° C. for 2 hrs to cover the bottom of the PDMS flexible substate.

Step 4, channel filling based on ultrasonic driving of liquid metal: the PMMA board carrying the flexible substrate was clamped on a TC4 fixture with bolts, wherein the fixture was used for conducting high-power ultrasound; liquid metal was injected into the liquid metal chamber in the PDMS flexible substrate by means of an injector, wherein if the dimension of the channel was less than 50 μm, the liquid metal would be filled in the whole chamber rather than being filled along the channel. An ultrasonic welding machine, positioned 30-40 mm away from the PDMS flexible substrate on the other side of the titanium alloy fixture, applied ultrasound at a power of 400-800 W to drive the liquid metal in the chamber to fill in the channel.

Specifically, to ensure effective conduction of ultrasound, an ultrasonic probe was pressed on the fixture by means of an air compressor and vibrated vertically to apply ultrasound. The pressure intensity of the air compressor should be at least 0.3 MPa or over to realize effective conduction of ultrasound to guarantee the quality of the channel filled with liquid metal. If the pressure intensity of the air compressor is too high, vibrations of the ultrasonic probe will be hindered, thus affecting experimental results. The pressure intensity of the air compressor used for experiments is recommended to be 0.3-0.5 MPa.

Step 5, the PDMS flexible substrate filled with the liquid metal was stripped from the PMMA board by means of a scalpel and was cut if necessary to obtain a liquid metal flexible circuit.

The limit dimension of channels that can be filled by the traditional injection method is 50 μm, and the substrate will be destroyed in a case where the channel dimension is less than 50 μm. The ultrasonic driving method adopted in the invention can generate an acoustic pressure gradient in liquid metal to drive the liquid metal to flow, thus breaking through the limit of 50 μm and realizing filling of channels as fine as 750 nm.

The traditional indirect method presses liquid metal into a channel by means of a pressure difference between an inlet and an outlet of the channel. Because the liquid metal has high surface tension and a larger proportion of the substrate should not be wetted by the liquid metal, the required pressure difference will be higher with the decrease in the channel dimension. The ultrasonic driving method induces a non-uniform acoustic pressure distribution to be generated in the liquid metal to press the liquid metal from a positive-acoustic pressure region (the liquid metal chamber) into a negative-acoustic pressure region (the channel) by means of an acoustic pressure gradient, and due to the anchoring and adhering effect of an oxide film of Ga-based liquid metal, it is ensured that the liquid metal will not flow back under the action of surface tension, such that the liquid metal is ultrasonically driven to filled in an ultra-fine channel. In addition, because no matter how complex the pattern is, the inside of the channel is always a negative-acoustic pressure region, thus preventing the situation where the channel cannot be completely filled because liquid metal flows out along a path with the minimum flow resistance

In the above steps, the ultrasonic driving method was used to drive the liquid metal to fill in the channel to prepare the flexible electronic circuit, the channel was completely filled without voids and other defects, and the processing efficiency was high. In this embodiment, channels with a length of 8 mm and the same width/height (the width/height was: 2 μm, 10 μm, 25 μm, 50 μm and 100 μm) were obtained.

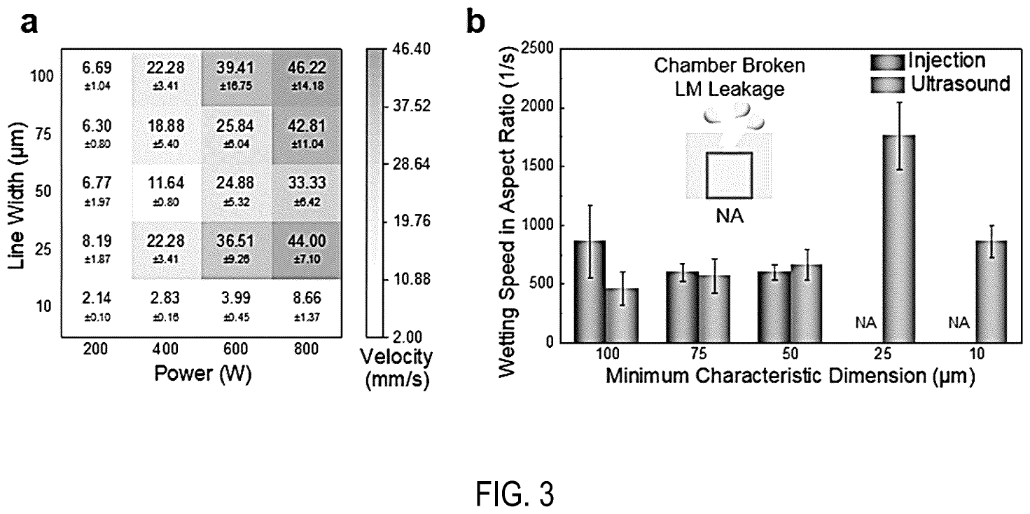

In this embodiment, ultrasonic power of 400 W, 600 W and 800 W was used to drive the liquid metal to fill the channel respectively, the filling velocities were recorded, and the specific results are shown in a of FIG. 3. The filling velocities of the ultrasonic driving method was compared with the filling velocity of the traditional injection method, as shown in b of FIG. 3. It can be seen, from velocity statistics, that the filling velocity of the ultrasonic driving method increases with the increase in applied ultrasonic power and the channel dimension; when 200 W ultrasonic power is used filling in a 10 μm channel, the filling velocity is minimum and is 2.14 mm/s, and the filling speed is maintained at mm/s; and when 800 W ultrasonic power is used filling in a 100 μm channel, the filling velocity is 46.22 mm/s.

The filling velocity of the ultrasonic driving method and the filling velocity of the traditional injection method under different channel dimensions were also compared, as shown in b of FIG. 3. It can be seen from b of FIG. 3 that the injection method is superior for large channels (>100 μm); for channels with a dimension of about 75 μm, the filling velocity of the ultrasonic driving method is approximately identical with the filling velocity of the injection method (˜48 mm/s); and for channels with a dimension less than 50 μm, the injection method is not applicable anymore because an excessively high pressure will destroy the channels, leading to a leakage of liquid metal, and the ultrasonic driving method is still applicable and has a high filling velocity.

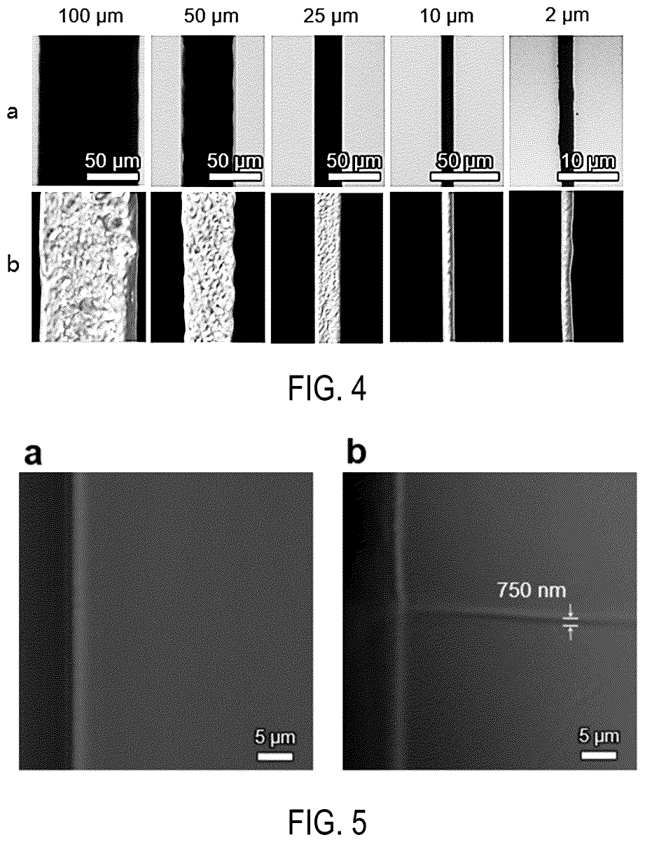

Then, the filling effect of channels filled based on ultrasonic driving of liquid metal was observed. Channels with widths/heights of 2 μm, 10 μm, 25 μm, 50 μm and 100 μm were selected; the channels were observed with an optical microscope, and observation results are shown in a of FIG. 4; and the channels were also observed by Micro-CT scanning, and observation results are shown in b of FIG. 4. The observation results obtained by the optical microscope indicate that the channels were completely filled with liquid metal, and the observation results obtained by Micro-CT scanning prove that the liquid metal conductive circuit prepared by the ultrasonic driving method had no defects or voids, indicating that the ultrasonic driving method can be used as a reliable method for preparing liquid metal flexible conductive circuits.

A channel with a diameter of 750 nm and a length of 200 μm was printed by a Nanoscribe two-photon printer, the nano flexible channel was filled with liquid metal under the excitation of ultrasound, and the filling result is shown in FIG. 5. It can be seen from FIG. 5 that the channel was completely filled. This result is the highest accuracy that can be obtained by indirect liquid metal patterning methods disclosed at present.

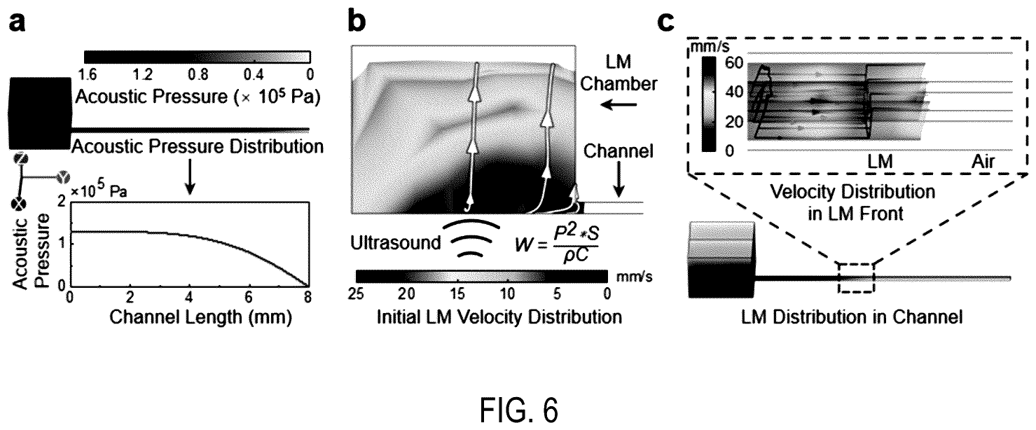

Ultrasound will lead to a non-uniform acoustic pressure distribution in liquid metal, and an acoustic gradient will generate a force to drive the liquid metal to flow. Specifically, the simulation result of the process of filling the channel by means of ultrasonic driving of liquid metal in the chamber is shown in FIG. 6. During simulation, the ultrasonic power applied was 800 W, and the other conditions were the same as the above experimental conditions. As shown in a of FIG. 6 which illustrates acoustic pressure distributions in the chamber and the channel, wherein the liquid metal chamber is square, and the channel is shaped like a long stick and has a dimension of 100 μm. When ultrasound is applied, the acoustic pressure may be distributed non-uniformly, wherein the maximum acoustic pressure (1.3*10⁵ Pa) is in the liquid metal chamber, and the minimum acoustic pressure (0 Pa) is at the outlet of the channel, such that the acoustic pressure gradient drives the liquid metal to fill in the channel. As shown in b of FIG. 6 which illustrate the velocity distribution and flow line of the liquid metal in the chamber, wherein the flow line indicted by the white arrow reflects the flow trajectory of liquid metal in the chamber, and the flow trajectory of the liquid metal at the bottom points to the channel, further indicating that the acoustic pressure drives the liquid metal to flow. As shown in c of FIG. 6 illustrates the liquid metal filling process, the flow velocity and flow line at the junction of the front edge of the liquid metal and air are simulated, the peak of the flow velocity is 60 mm/s, which is higher than the average velocity 46.22 mm/s because the surface of the Ga-based liquid metal will be oxidized in the atmospheric environment to generate an oxide film to hinder flowing of the liquid metal.

### Embodiment 2

Liquid metal is ultrasonically driven to fill in micro-channels of complex patterns.

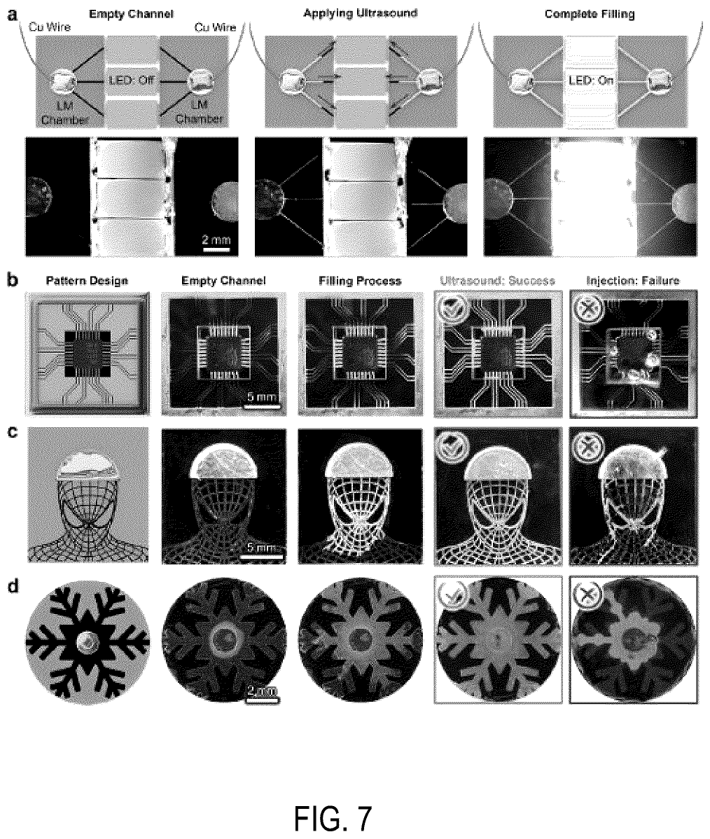

Micro-channels with different complex pattern structures were prepared by the method in Embodiment 1 and filled by the ultrasonic driving method. These complex structures included: a 3-channel LED array, a 32-channel pattern connected with a single-chip microcomputer, an interconnected-channel spider-man pattern, a snowflake pattern with a planar structure and blind-hole structures, and the like. The results are shown in FIG. 7. It can be seen from FIG. 7 that these patterns were effectively filled, and this indicates that the ultrasonic driving method can prepare complex conductive circuits that cannot be prepared by the traditional indirect method, further proving the universality of the ultrasonic driving method.

Specifically, in a of FIG. 7, three straight channels with different lengths were formed in each of two PDMS substates, one end of each channel was connected to a liquid metal chamber, and the other end of each channel was connected to a pin of an LED lamp. Two liquid metal chambers were connected by means of a copper wire and a constant 3V voltage was applied, and after ultrasound was applied, the three channels were completely filled almost at the same time and were connected to the LED pins by means of outlets, thus turning on the LED lamp array.

As shown in b of FIG. 7 which illustrates a liquid metal chamber configured as a rectangular structure. One ends of 32 independent channels were connected to the liquid metal chamber, and the other ends of the 32 independent channels were connected to a single-chip microcomputer with 32 pins. Within 1 s after ultrasound was applied, all the channels were completely filled and electrically connected to the single-chip microcomputer with 32 pins. On the contrary, only five channels were connected by the injection method, leaking LM was aggregated into a ball due to high surface tension and leaded to short-circuiting, thus resulting in a failure of the circuit. The successful filling of the multiple channels indicates that the ultrasonic driving method can fulfill mass production of flexible circuits.

Interconnected liquid metal structures have high application value in lightweight electromagnetic shielding. In this embodiment, a spider-man pattern with the similar structure was designed and filled by the ultrasonic driving method, and the results are shown in c of FIG. 7. Within 1 s after ultrasound was applied, 70% of the interconnected pattern was effectively filled with liquid metal, and the whole pattern was filled 1.2 s later. On the contrary, less than 30% of the channel was filled by the injection method, and a leakage of the liquid metal was caused.

In addition, in this embodiment, a snowflake pattern with both a planar structure and blind-hole structures, including a planar hexagram pattern in the middle of six branch channels, was designed, and each of the branch channels had four blind-hole structures. Under the action of ultrasound, the pattern was completely filled with liquid metal within 1 s, as shown in d of FIG. 7. On the contrary, the injection method failed to fill the blind-hole structures and even failed to completely and effectively fill sharp structures of the planar pattern. The planar structure of the liquid metal can be used for airtight packaging of flexible devices (such as flexible cells and capacitors), and the blind-hole structures can be applied to electric connection of three-dimensional integrated circuits in the future. All these structures have high application value.

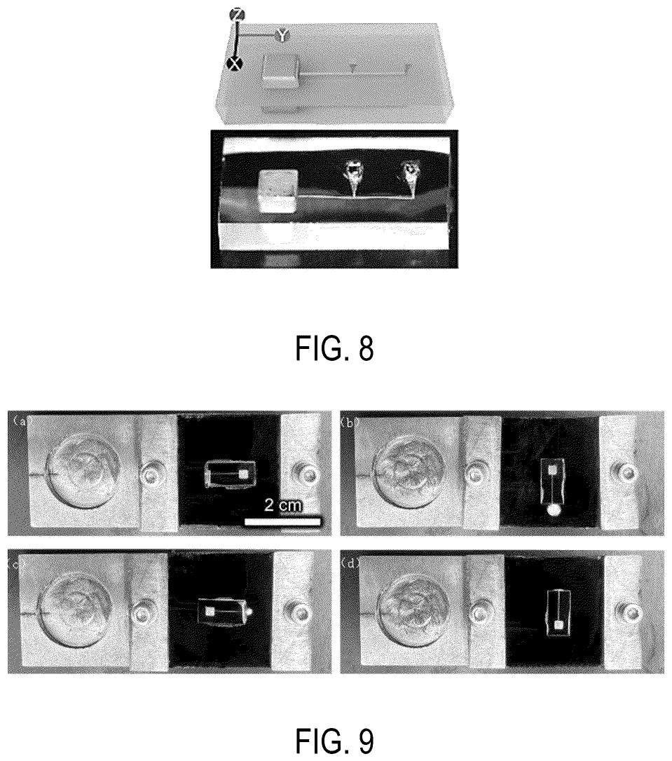

Finally, in this embodiment, a comb-like structure, which has two vertical channels connected with the outside, was designed, and obtained results are shown in FIG. 8. It can be seen from FIG. 8 that under the action of ultrasound, the liquid metal can overcome the gravity to completely fill in the channel, further indicating that the ultrasonic driving method can be used for constructing three-dimensional liquid metal flexible conductive circuits in the future.

### Embodiment 3

Based on Embodiment 1, the position where the ultrasound was applied in Step 4 was changed to apply ultrasound at different positions and in different directions with respect to the channel to obtain the results shown in FIG. 9. It can be seen from FIG. 9 that the channel was completely filled.

Further, in a case where ultrasound was applied at a position 40 mm away from the channel, the channel was also filled, and the filling effect is the same as that in FIG. 9, indicating that within 40 mm, the experimental effect will not be affected by the change of the distance between the liquid metal chamber and the ultrasound point and the direction of the channel.

Compared with the prior art, the invention has the following beneficial effects:

By adopting the technical solution of the invention, ultrasound is introduced as a pressure source to drive liquid metal to fill in a micro-nano channel to obtain a flexible electronic conductive circuit, submicron channels as fine as 750 nm can be filled, effective filling of multi-channel structures, complex interconnected-channel structures and blind-hole structures can be realized, and the filling process can be completed within several seconds, such that the velocity, accuracy and efficiency are high, and the cost is low.

The invention is described in further detail below in conjunction with specific preferred embodiments, and the specific embodiments of the invention are not limited to the above description. For those skilled in the art, some simple deductions or substitutions can be made without departing from the concept of the invention, and all these simple deductions or substitutions should also fall within the protection scope of the invention.

What is claimed is:

1. A method for preparing a micro-nano flexible conductive circuit based on ultrasonic driving of liquid metal, comprising the following steps:
S1, preparing a mold with a channel pattern and a liquid metal chamber, and adding a well-mixed flexible substrate resin mixture into the mold;
S2, placing the mold full of the flexible substrate resin mixture in a vacuum environment to eliminate bubbles, curing, and stripping a cured flexible substrate from the mold to obtain a bottom-uncovered flexible substrate;
S3, covering a bottom of the bottom-uncovered flexible substrate with a base plate to obtain a bottom-covered flexible substrate mold;
S4, fixing the bottom-covered flexible substrate mold on a titanium alloy fixture table, injecting liquid metal into the liquid metal chamber of the bottom-covered flexible substrate mold, positioning an ultrasonic welding machine on a side of the fixture table and the bottom-covered flexible substrate mold on an opposite side, and then applying ultrasound to ultrasonically drive the liquid metal in the liquid metal chamber to fill the channel; and
S5, removing the base plate from the bottom-covered flexible substrate mold to obtain a liquid metal flexible conductive circuit.

2. The method for preparing a micro-nano flexible conductive circuit based on ultrasonic driving of liquid metal according to claim 1, wherein in S4, power of the ultrasound is 400-800 W.

3. The method for preparing a micro-nano flexible conductive circuit based on ultrasonic driving of liquid metal according to claim 2, wherein in S4, an ultrasonic probe is used to vertically apply ultrasound to the fixture table.

4. The method for preparing a micro-nano flexible conductive circuit based on ultrasonic driving of liquid metal according to claim 3, wherein in S4, the ultrasonic probe is pressed on the fixture table by means of an air pressure of an air compressor, and a pressure intensity of the air compressor is 0.3-0.5 MPa.

5. The method for preparing a micro-nano flexible conductive circuit based on ultrasonic driving of liquid metal according to claim 4, wherein a distance between the ultrasonic probe and the bottom-covered flexible substrate mold is not greater than 100 mm.

6. The method for preparing a micro-nano flexible conductive circuit based on ultrasonic driving of liquid metal according to claim 4, wherein in S3, the bottom of the bottom-uncovered flexible substrate is connected to the base plate by means of the flexible substrate resin mixture and cured to obtain the bottom-covered flexible substrate mold.

7. The method for preparing a micro-nano flexible conductive circuit based on ultrasonic driving of liquid metal according to claim 1, wherein the base plate is a PMMA board, and the flexible substrate resin mixture comprises PDMS and a curing agent.

8. The method for preparing a micro-nano flexible conductive circuit based on ultrasonic driving of liquid metal according to claim 2, wherein the base plate is a PMMA board, and the flexible substrate resin mixture comprises PDMS and a curing agent.

9. The method for preparing a micro-nano flexible conductive circuit based on ultrasonic driving of liquid metal according to claim 3, wherein the base plate is a PMMA board, and the flexible substrate resin mixture comprises PDMS and a curing agent.

10. The method for preparing a micro-nano flexible conductive circuit based on ultrasonic driving of liquid metal according to claim 4, wherein the base plate is a PMMA board, and the flexible substrate resin mixture comprises PDMS and a curing agent.

11. The method for preparing a micro-nano flexible conductive circuit based on ultrasonic driving of liquid metal according to claim 5, wherein the base plate is a PMMA board, and the flexible substrate resin mixture comprises PDMS and a curing agent.

12. The method for preparing a micro-nano flexible conductive circuit based on ultrasonic driving of liquid metal according to claim 6, wherein the base plate is a PMMA board, and the flexible substrate resin mixture comprises PDMS and a curing agent.

13. The method for preparing a micro-nano flexible conductive circuit based on ultrasonic driving of liquid metal according to claim 1, wherein the metal fixture table is made from titanium alloy or aluminum alloy.

14. The method for preparing a micro-nano flexible conductive circuit based on ultrasonic driving of liquid metal according to claim 2, wherein the metal fixture table is made from titanium alloy or aluminum alloy.

15. The method for preparing a micro-nano flexible conductive circuit based on ultrasonic driving of liquid metal according to claim 3, wherein the metal fixture table is made from titanium alloy or aluminum alloy.

16. The method for preparing a micro-nano flexible conductive circuit based on ultrasonic driving of liquid metal according to claim 4, wherein the metal fixture table is made from titanium alloy or aluminum alloy.

17. The method for preparing a micro-nano flexible conductive circuit based on ultrasonic driving of liquid metal according to claim 5, wherein the metal fixture table is made from titanium alloy or aluminum alloy.

18. The method for preparing a micro-nano flexible conductive circuit based on ultrasonic driving of liquid metal according to claim 6, wherein the metal fixture table is made from titanium alloy or aluminum alloy.

19. A micro conductive circuit, being prepared by the method for preparing a micro-nano flexible conductive circuit based on ultrasonic driving of liquid metal according to claim 1.

20. A flexible electronic device, comprising the micro conductive circuit according to claim 19.
